(19) United States
(12) Patent Application Publication
(10) Pub. No.: US 2026/0285774 A1
(43) Pub. Date: Sep. 24, 2026

(54) METAL CARBIDE-COATED CARBON MATERIAL

(71) Applicant: SHIN-ETSU CHEMICAL CO., LTD., Tokyo (JP)

(72) Inventors: Akihiro HIRATE, Takasaki-shi (JP); Naoya MIYAJIMA, Annaka-shi (JP); Waichi YAMAMURA, Annaka-shi (JP); Shoji KANO, Takasaki-shi (JP)

(73) Assignee: SHIN-ETSU CHEMICAL CO., LTD., Tokyo (JP)

(21) Appl. No.: 19/475,495

(22) PCT Filed: Apr. 1, 2024
(86) PCT No.: PCT/JP2024/013437

§ 371 Date: Oct. 15, 2025

(30) Foreign Application Priority Data
May 1, 2023 (JP) 2023-075400

(51) Int. Cl. C04B 41/50; C04B 35/536; C04B 41/45; C04B 41/87

(52) U.S. Cl. CPC C04B 41/5057; C04B 35/536; C04B 41/4531; C04B 41/87; C04B 2235/401; C04B 2235/402; C04B 2235/404; C04B 2235/405; C04B 2235/425; C04B 2235/428; C04B 2235/963

(57) ABSTRACT

The present invention relates to a metal carbide-coated carbon material including a carbon substrate containing carbon as a main component and a metal carbide coating film covering at least part of the carbon substrate, in which the metal carbide constituting the metal carbide coating film is at least one metal carbide selected from the group consisting of tantalum carbide, niobium carbide, zirconium carbide, hafnium carbide, and tungsten carbide, in which the carbon substrate contains at least one element selected from the group consisting of aluminum, iron, magnesium, titanium, silicon, calcium, vanadium, nickel, sodium, potassium, and sulfur, and in which the total concentration of aluminum, iron, magnesium, titanium, silicon, calcium, vanadium, nickel, sodium, potassium, and sulfur in the carbon substrate is 10 mass ppm or more and 10,000 mass ppm or less. The present invention can provide a metal carbide-coated carbon material from which outgassing is less likely to occur in a high-temperature environment.

### TECHNICAL FIELD

The present invention relates to a metal carbide-coated carbon material in which the surface of a carbon substrate is covered with a metal carbide coating film.

### BACKGROUND ART

Wide-bandgap semiconductors typified by SiC and GaN have not only higher dielectric breakdown field strength and better heat resistance but also lower loss than Si semiconductors and are thus suitable for power semiconductors. However, with wide-bandgap semiconductors, the production cost of wafers is higher as compared with Si semiconductors. Therefore, there is a need to reduce the production cost of wide-bandgap semiconductor wafers.

A major impact on the production cost of wide-bandgap semiconductor wafers is the cost incurred in the crystal growth and epitaxial growth steps for wide-bandgap semiconductors, and improvement in yield in these steps is required to reduce the production cost of wide-bandgap semiconductor wafers.

There are several factors that may reduce the yield in the crystal growth and epitaxial growth steps for wide-bandgap semiconductors, one of which is outgassing from carbon substrates used as crucibles, guide components, and susceptors. Outgassing is the result of sublimation of a carbon substrate itself and desorption of hydrocarbon gases previously adsorbed on the carbon substrate, and these gases may cause a change in crystal orientation during crystal growth, resulting in a lower yield.

A solution to this problem is coating of the carbon substrate with a metal carbide film. Tantalum carbide, niobium carbide, zirconium carbide, hafnium carbide, tungsten carbide, and other metal carbides have high melting points and excellent chemical stability, strength, toughness, and corrosion resistance. For this reason, metal carbide coating of carbon substrates can improve the heat resistance, chemical stability, strength, toughness, and corrosion resistance of the carbon substrates and can also suppress outgassing from the carbon substrates.

In addition, high-purification treatment of carbon substrates themselves is known to suppress outgassing. In fact, carbon substrates subjected to high-purification treatment are used in PTL 1, and NPL 1 reports that high-purification treatment of carbon substrates can reduce the amounts of gases thermally desorbed from the carbon substrates.

### CITATION LIST

### Patent Literature

PTL 1: JP 5502721 B

### Non Patent Literature

NPL 1: Special graphite products catalog of Toyo Tanso Co., Ltd., Internet: https://www.toyotanso.co.jp/Products/download/Summary of Invention

### Technical Problem

However, when the carbon substrates described in PTL 1 and the carbon substrates described in NPL 1 were coated with a metal carbide film and used for an apparatus for wide-bandgap semiconductor production, the suppression of outgassing during crystal growth and epitaxial growth steps was found to be insufficient.

Therefore, an object of the present invention is to provide a metal carbide-coated carbon material from which outgassing is less likely to occur in a high-temperature environment.

### Solution to Problem

The present inventors conducted intensive and extensive investigations, and finally found that when the total concentration of aluminum, iron, magnesium, titanium, silicon, calcium, vanadium, nickel, sodium, potassium, and sulfur in the carbide substrate in the metal carbide-coated carbon material is 10 mass ppm or more and 10,000 mass ppm or less, outgassing from the metal carbide-coated carbon material is less likely to occur in a high-temperature environment. On the basis of this finding, the present inventors have completed the present invention. The scope of the present invention is as follows.

[1] A metal carbide-coated carbon material including a carbon substrate containing carbon as a main component and a metal carbide coating film covering at least part of the carbon substrate,
in which the metal carbide constituting the metal carbide coating film is at least one metal carbide selected from the group consisting of tantalum carbide, niobium carbide, zirconium carbide, hafnium carbide, and tungsten carbide,
in which the carbon substrate contains at least one element selected from the group consisting of aluminum, iron, magnesium, titanium, silicon, calcium, vanadium, nickel, sodium, potassium, and sulfur, and
in which the total concentration of aluminum, iron, magnesium, titanium, silicon, calcium, vanadium, nickel, sodium, potassium, and sulfur in the carbon substrate is 10 mass ppm or more and 10,000 mass ppm or less.
   [2] The metal carbide-coated carbon material according to the above [1], in which the concentration of iron in the carbon substrate is 1 mass ppm or more and 10,000 mass ppm or less.
   [3] The metal carbide-coated carbon material according to the above [1] or [2], in which the concentration of titanium in the carbon substrate is 0.1 mass ppm or more and 10,000 mass ppm or less.
   [4] The metal carbide-coated carbon material according to any one of the above [1] to [3], in which the concentration of magnesium in the carbon substrate is 0.1 mass ppm or more and 10,000 mass ppm or less.
   [5] The metal carbide-coated carbon material according to any one of the above [1] to [4], in which the concentration of silicon in the carbon substrate is 0.1 mass ppm or more and 10,000 mass ppm or less.
   [6] The metal carbide-coated carbon material according to any one of the above [1] to [5], in which the concentration of calcium in the carbon substrate is 0.1 mass ppm or more and 10,000 mass ppm or less.
   [7] The metal carbide-coated carbon material according to any one of the above [1] to [6], in which the concentration of vanadium in the carbon substrate is 0.1 mass ppm or more and 10,000 mass ppm or less.
   [8] The metal carbide-coated carbon material according to any one of the above [1] to [7], in which the concentration of sodium in the carbon substrate is 0.1 mass ppm or more and 10,000 mass ppm or less.
   [9] The metal carbide-coated carbon material according to any one of the above [1] to [8], in which the concentration of potassium in the carbon substrate is 0.1 mass ppm or more and 10,000 mass ppm or less.
   [10] The metal carbide-coated carbon material according to any one of the above [1] to [9], in which the concentration of sulfur in the carbon substrate is 0.1 mass ppm or more and 10,000 mass ppm or less.
   [11] The metal carbide-coated carbon material according to any one of the above [1] to [10], in which the metal carbide coating film has a film thickness of 10 μm or more and 100 μm or less.
   [12] The metal carbide-coated carbon material according to any one of the above [1] to [11], in which the surface of the metal carbide coating film has an arithmetic average roughness Ra of 0.1 μm or more and 9.5 μm or less.
   [13] The metal carbide-coated carbon material according to any one of the above [1] to [12], in which the surface of the carbon substrate has an arithmetic average roughness Ra of 0.1 μm or more and 10.0 μm or less.
   [14] The metal carbide-coated carbon material according to any one of the above [1] to [13], in which the metal carbide constituting the metal carbide coating film is tantalum carbide.

### Advantageous Effects of Invention

The present invention can provide a metal carbide-coated carbon material from which outgassing is less likely to occur in a high-temperature environment.

### BRIEF DESCRIPTION OF DRAWINGS

FIG. 1 is a schematic view of a hot-wall low-pressure CVD apparatus according to an embodiment of the present invention.

FIG. 2 is a schematic view of a setup for a corrosion resistance testing method according to an embodiment of the present invention.

FIG. 3 is a schematic view illustrating a method for measuring the adhesion strength of a metal carbide coating film according to an embodiment of the present invention.

FIG. 4 shows the results of a corrosion resistance test of the tantalum carbide-coated carbon materials of Examples 1 to 4 and Comparative Example 1.

### DESCRIPTION OF EMBODIMENTS

The metal carbide-coated carbon material according to the present invention will be described using a tantalum carbide-coated carbon material as an example.

### Tantalum Carbide-Coated Carbon Material

A tantalum carbide-coated carbon material according to one embodiment of the present invention includes a carbon substrate containing carbon as a main component and a tantalum carbide coating film covering at least part of the carbon substrate, in which the carbon substrate contains at least one element selected from the group consisting of aluminum, iron, magnesium, titanium, silicon, calcium, vanadium, nickel, sodium, potassium, and sulfur, and in which the total concentration of aluminum, iron, magnesium, titanium, silicon, calcium, vanadium, nickel, sodium, potassium, and sulfur in the carbon substrate is 10 mass ppm or more and 10,000 mass ppm or less.

### Carbon Substrate

The carbon substrate in the tantalum carbide-coated carbon material according to one embodiment of the present invention is a substrate containing carbon as a main component. The carbon substrate may further contain chlorine. Examples of the material of the carbon substrate include isotropic graphite, extruded graphite, pyrolytic graphite, and carbon fiber reinforced carbon matrix composites (C/C composites). The shape and properties of the carbon substrate are not particularly limited, and the carbon substrate can be processed into any shape according to the application and the like.

### Total Elemental Concentration

The carbon substrate in the tantalum carbide-coated carbon material according to one embodiment of the present invention contains at least one element selected from the group consisting of aluminum, iron, magnesium, titanium, silicon, calcium, vanadium, nickel, sodium, potassium, and sulfur. The total concentration of aluminum, iron, magnesium, titanium, silicon, calcium, vanadium, nickel, sodium, potassium, and sulfur in the carbon substrate is 10 mass ppm or more and 10,000 mass ppm or less. When the total concentration of the above elements is more than 10,000 mass ppm, the amount of outgassing from the carbon substrate in a high-temperature environment increases. As a result, when the tantalum carbide-coated carbon material using such a carbon substrate is used for an apparatus for wide-bandgap semiconductor production, the yield of wide-bandgap semiconductors may be reduced. Even when the total concentration of the above elements is reduced to less than 10 mass ppm, the amount of outgassing from the carbon substrate in a high-temperature environment cannot be reduced much as compared with when the total concentration of the above elements is 10 mass ppm. That is, reducing the total concentration of the above elements to less than 10 mass ppm increases the production cost of the carbon substrate, which may result in an insufficient reduction in the production cost of wide-bandgap semiconductor wafers. In this view, the total concentration of the above elements is preferably 15 mass ppm or more and 5,000 mass ppm or less, and more preferably 20 mass ppm or more and 1,000 ppm or less. The respective concentrations of the above elements in the carbon substrate can be measured by the method described in the Examples below. The total concentration of the above elements can be adjusted by, for example, heating the carbon substrate in halogen gas at about 2,000° C. to volatilize the above elements as low-boiling-point halides from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Iron

The concentration of iron in the carbon substrate in the tantalum carbide-coated carbon material according to one embodiment of the present invention is preferably 1 mass ppm or more and 10,000 mass ppm or less. When the concentration of iron is 10,000 mass ppm or less, outgassing from the carbon substrate in a high-temperature environment is further less likely to occur. When the concentration of iron is 1 mass ppm or more, the increase in the cost of the carbon substrate due to further reduction in the concentration of iron can be prevented. In this view, the concentration of iron is more preferably 1 mass ppm or more and 4,000 mass ppm or less, still more preferably 1 mass ppm or more and 1,000 ppm or less, even more preferably 1 mass ppm or more and 100 mass ppm or less, and even more preferably 1 mass ppm or more and 50 mass ppm or less. The concentration of iron in the carbon substrate can be measured by the method described in the Examples below. The concentration of iron can be adjusted by, for example, heating the carbon substrate in halogen gas at about 2,000° C. to volatilize iron as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Titanium

The concentration of titanium in the carbon substrate in the tantalum carbide-coated carbon material according to one embodiment of the present invention is preferably 0.1 mass ppm or more and 10,000 mass ppm or less. When the concentration of titanium is 10,000 mass ppm or less, outgassing from the carbon substrate in a high-temperature environment is further less likely to occur. When the concentration of titanium is 0.1 mass ppm or more, the increase in the cost of the carbon substrate due to further reduction in the concentration of titanium can be prevented. In this view, the concentration of titanium is more preferably 0.1 mass ppm or more and 2,000 mass ppm or less, still more preferably 0.1 mass ppm or more and 1,000 mass ppm or less, even more preferably 0.1 mass ppm or more and 500 mass ppm or less, even more preferably 0.1 mass ppm or more and 100 mass ppm or less, even more preferably 0.1 mass ppm or more and 50 mass ppm or less, even more preferably 0.1 mass ppm or more and 10 mass ppm or less, even more preferably 0.1 mass ppm or more and 5 mass ppm or less, and even more preferably 0.1 mass ppm or more and 3 mass ppm or less. The concentration of titanium in the carbon substrate can be measured by the method described in the Examples below. The concentration of titanium can be adjusted by, for example, heating the carbon substrate in halogen gas at about 2,000° C. to volatilize titanium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Magnesium

The concentration of magnesium in the carbon substrate in the tantalum carbide-coated carbon material according to one embodiment of the present invention is preferably 0.1 mass ppm or more and 10,000 mass ppm or less. When the concentration of magnesium is 10,000 mass ppm or less, outgassing from the carbon substrate in a high-temperature environment is further less likely to occur. When the concentration of magnesium is 0.1 mass ppm or more, the increase in the cost of the carbon substrate due to further reduction in the concentration of magnesium can be prevented. In this view, the concentration of magnesium is more preferably 0.1 mass ppm or more and 100 mass ppm or less, still more preferably 0.1 mass ppm or more and 50 mass ppm or less, even more preferably 0.1 mass ppm or more and 20 mass ppm or less, even more preferably 0.1 mass ppm or more and 10 mass ppm or less, even more preferably 0.1 mass ppm or more and 5 mass ppm or less, and even more preferably 0.1 mass ppm or more and 2 mass ppm or less. The concentration of magnesium in the carbon substrate can be measured by the method described in the Examples below. The concentration of magnesium can be adjusted by, for example, heating the carbon substrate in halogen gas at about 2,000° C. to volatilize magnesium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Silicon

The concentration of silicon in the carbon substrate in the tantalum carbide-coated carbon material according to one embodiment of the present invention is preferably 0.1 mass ppm or more and 10,000 mass ppm or less. When the concentration of silicon is 10,000 mass ppm or less, outgassing from the carbon substrate in a high-temperature environment is further less likely to occur. When the concentration of silicon is 0.1 mass ppm or more, the increase in the cost of the carbon substrate due to further reduction in the concentration of silicon can be prevented. In this view, the concentration of silicon is more preferably 0.1 mass ppm or more and 1,000 mass ppm or less, still more preferably 0.1 mass ppm or more and 500 mass ppm or less, even more preferably 0.1 mass ppm or more and 200 mass ppm or less, even more preferably 0.1 mass ppm or more and 100 mass ppm or less, even more preferably 0.1 mass ppm or more and 50 mass ppm or less, and even more preferably 0.1 mass ppm or more and 30 mass ppm or less. The concentration of silicon in the carbon substrate can be measured by the method described in the Examples below. The concentration of silicon can be adjusted by, for example, heating the carbon substrate in halogen gas at about 2,000° C. to volatilize silicon as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Calcium

The concentration of calcium in the carbon substrate in the tantalum carbide-coated carbon material according to one embodiment of the present invention is preferably 0.1 mass ppm or more and 10,000 mass ppm or less. When the concentration of calcium is 10,000 mass ppm or less, outgassing from the carbon substrate in a high-temperature environment is further less likely to occur. When the concentration of calcium is 0.1 mass ppm or more, the increase in the cost of the carbon substrate due to further reduction in the concentration of calcium can be prevented. In this view, the concentration of calcium is more preferably 0.1 mass ppm or more and 2,000 mass ppm or less, still more preferably 0.1 mass ppm or more and 1,000 mass ppm or less, even more preferably 0.1 mass ppm or more and 100 mass ppm or less, even more preferably 0.1 mass ppm or more and 50 mass ppm or less, and even more preferably 0.1 mass ppm or more and 10 mass ppm or less. The concentration of calcium in the carbon substrate can be measured by the method described in the Examples below. The concentration of calcium can be adjusted by, for example, heating the carbon substrate in halogen gas at about 2,000° C. to volatilize calcium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Vanadium

The concentration of vanadium in the carbon substrate in the tantalum carbide-coated carbon material according to one embodiment of the present invention is preferably 0.1 mass ppm or more and 10,000 mass ppm or less. When the concentration of vanadium is 10,000 mass ppm or less, outgassing from the carbon substrate in a high-temperature environment is further less likely to occur. When the concentration of vanadium is 0.1 mass ppm or more, the increase in the cost of the carbon substrate due to further reduction in the concentration of vanadium can be prevented. In this view, the concentration of vanadium is more preferably 0.1 mass ppm or more and 1,000 mass ppm or less, still more preferably 0.1 mass ppm or more and 500 mass ppm or less, even more preferably 0.1 mass ppm or more and 100 mass ppm or less, even more preferably 0.1 mass ppm or more and 50 mass ppm or less, even more preferably 0.1 mass ppm or more and 10 mass ppm or less, and even more preferably 0.1 mass ppm or more and 5 mass ppm or less. The concentration of vanadium in the carbon substrate can be measured by the method described in the Examples below. The concentration of vanadium can be adjusted by, for example, heating the carbon substrate in halogen gas at about 2,000° C. to volatilize vanadium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Sodium

The concentration of sodium in the carbon substrate in the tantalum carbide-coated carbon material according to one embodiment of the present invention is preferably 0.1 mass ppm or more and 10,000 mass ppm or less. When the concentration of sodium is 10,000 mass ppm or less, outgassing from the carbon substrate in a high-temperature environment is further less likely to occur. When the concentration of sodium is 0.1 mass ppm or more, the increase in the cost of the carbon substrate due to further reduction in the concentration of sodium can be prevented. In this view, the concentration of sodium is more preferably 0.1 mass ppm or more and 100 mass ppm or less, still more preferably 0.1 mass ppm or more and 50 ppm or less, even more preferably 0.1 mass ppm or more and 20 mass ppm or less, and even more preferably 0.1 mass ppm or more and 5 mass ppm or less. The concentration of sodium in the carbon substrate can be measured by the method described in the Examples below. The concentration of sodium can be adjusted by, for example, heating the carbon substrate in halogen gas at about 2,000° C. to volatilize sodium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Potassium

The concentration of potassium in the carbon substrate in the tantalum carbide-coated carbon material according to one embodiment of the present invention is preferably 0.1 mass ppm or more and 10,000 mass ppm or less. When the concentration of potassium is 10,000 mass ppm or less, outgassing from the carbon substrate in a high-temperature environment is further less likely to occur. When the concentration of potassium is 0.1 mass ppm or more, the increase in the cost of the carbon substrate due to further reduction in the concentration of potassium can be prevented. In this view, the concentration of potassium is more preferably 0.1 mass ppm or more and 100 mass ppm or less, still more preferably 0.1 mass ppm or more and 50 mass ppm or less, even more preferably 0.1 mass ppm or more and 20 mass ppm or less, even more preferably 0.1 mass ppm or more and 10 mass ppm or less, even more preferably 0.1 mass ppm or more and 5 mass ppm or less, even more preferably 0.1 mass ppm or more and 2 mass ppm or less, and even more preferably 0.1 mass ppm or more and 1 mass ppm or less. The concentration of potassium in the carbon substrate can be measured by the method described in the Examples below. The concentration of potassium can be adjusted by, for example, heating the carbon substrate in halogen gas at about 2,000° C. to volatilize potassium as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Sulfur

The concentration of sulfur in the carbon substrate in the tantalum carbide-coated carbon material according to one embodiment of the present invention is preferably 0.1 mass ppm or more and 10,000 mass ppm or less. When the concentration of sulfur is 10,000 mass ppm or less, outgassing from the carbon substrate in a high-temperature environment is further less likely to occur. When the concentration of sulfur is 0.1 mass ppm or more, the increase in the cost of the carbon substrate due to further reduction in the concentration of sulfur can be prevented. In this view, the concentration of sulfur is more preferably 0.1 mass ppm or more and 100 mass ppm or less, still more preferably 0.1 mass ppm or more and 50 mass ppm or less, even more preferably 0.1 mass ppm or more and 20 mass ppm or less, even more preferably 0.1 mass ppm or more and 10 mass ppm or less, even more preferably 0.1 mass ppm or more and 5 mass ppm or less, even more preferably 0.1 mass ppm or more and 2 mass ppm or less, and even more preferably 0.1 mass ppm or more and 1 mass ppm or less. The concentration of sulfur in the carbon substrate can be measured by the method described in the Examples below. The concentration of sulfur can be adjusted by, for example, hydrogenating the carbon substrate to volatilize sulfur as hydrogen sulfide from the carbon substrate.

### Concentration of Aluminum

The concentration of aluminum in the carbon substrate in the tantalum carbide-coated carbon material according to one embodiment of the present invention is preferably 0.1 mass ppm or more and 10,000 mass ppm or less. When the concentration of aluminum is 10,000 mass ppm or less, outgassing from the carbon substrate in a high-temperature environment is further less likely to occur. When the concentration of aluminum is 0.1 mass ppm or more, the increase in the cost of the carbon substrate due to further reduction in the concentration of aluminum can be prevented. In this view, the concentration of aluminum is more preferably 0.1 mass ppm or more and 1,000 mass ppm or less, still more preferably 0.1 mass ppm or more and 100 ppm or less, even more preferably 0.1 mass ppm or more and 50 ppm or less, even more preferably 0.1 mass ppm or more and 20 mass ppm or less, and even more preferably 0.1 mass ppm or more and 5 mass ppm or less. The concentration of aluminum in the carbon substrate can be measured by the method described in the Examples below. The concentration of aluminum can be adjusted by, for example, heating the carbon substrate in halogen gas at about 2,000° C. to volatilize aluminum as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Concentration of Nickel

The concentration of nickel in the carbon substrate in the tantalum carbide-coated carbon material according to one embodiment of the present invention is preferably 0.1 mass ppm or more and 10,000 mass ppm or less. When the concentration of nickel is 10,000 mass ppm or less, outgassing from the carbon substrate in a high-temperature environment is further less likely to occur. When the concentration of nickel is 0.1 mass ppm or more, the increase in the cost of the carbon substrate due to further reduction in the concentration of nickel can be prevented. In this view, the concentration of nickel is more preferably 0.1 mass ppm or more and 1,000 mass ppm or less, still more preferably 0.1 mass ppm or more and 100 ppm or less, even more preferably 0.1 mass ppm or more and 50 ppm or less, even more preferably 0.1 mass ppm or more and 20 mass ppm or less, and even more preferably 0.1 mass ppm or more and 5 mass ppm or less. The concentration of nickel in the carbon substrate can be measured by the method described in the Examples below. The concentration of nickel can be adjusted by, for example, heating the carbon substrate in halogen gas at about 2,000° C. to volatilize nickel as a low-boiling-point halide from the carbon substrate. Specifically, a method for removing impurities using chlorine is described in Reference 1 (Kazuhiro Nagata, Tetsu-to-Hagane, Vol. 73, No. 9, pp. 1077-1081 (1987)).

### Arithmetic Surface Roughness Ra

The arithmetic average roughness Ra of the surface of the carbon substrate affects semiconductor single-crystal growth and epitaxial growth. A larger value of the arithmetic average roughness Ra of the surface of the carbon substrate tends to indicate a greater strength of delamination of the tantalum carbide coating film from the carbon substrate. For this reason, a larger value of the arithmetic average roughness Ra of the surface of the carbon substrate is preferable. However, when the arithmetic average roughness Ra of the surface of the carbon substrate is too large, the specific surface area of the carbon substrate is increased and cracking and delamination may occur. Thus, when such a tantalum carbide-coated carbon material is used as the components used for semiconductor single-crystal growth and epitaxial growth, the product life may be shortened. Therefore, in view of the product life of the tantalum carbide-coated carbon material, the arithmetic average roughness Ra of the surface of the carbon substrate is preferably 10.0 μm or less. In consideration of both the incidences of cracking and delamination of the carbon substrate and the tantalum carbide coating film, the arithmetic average roughness Ra of the surface of the carbon substrate is preferably 0.1 μm or more and 10.0 μm or less, and more preferably 2.0 μm or more and 6.0 μm or less. Within these ranges, a greater strength of delamination of the tantalum carbide coating film from the carbon substrate can be achieved, and when such a tantalum carbide-coated carbon material is used as the components for semiconductor single-crystal growth and epitaxial growth, a longer product life can be achieved. The arithmetic average roughness Ra of the surface of the carbon substrate is a value as measured according to JIS B 0633:2001 (ISO 4288:1996).

### Linear Thermal Expansion Coefficient

The linear thermal expansion coefficient of the carbon substrate is preferably 3.5×10⁻⁶/° C. or more and 8.2×10⁻⁶/° C. or less. When the linear thermal expansion coefficient of the carbon substrate is 3.5×10⁻⁶/° C. or more and 8.2× 10⁻⁶/° C. or less, microcracking in the tantalum carbide coating film can be further mitigated. In this view, the linear thermal expansion coefficient of the carbon substrate is more preferably 5.0×10⁻⁶ to 7.5×10⁻⁶/° C. The linear thermal expansion coefficient of the tantalum carbide coating film is about 6.3×10⁻⁶/° C. The linear thermal expansion coefficient of the carbon substrate can be measured in accordance with JIS R 1618.

### Tantalum Carbide Coating Film

The tantalum carbide coating film is a film containing tantalum carbide as a main component. The tantalum carbide coating film may cover part of the carbon substrate or the whole carbon substrate. The tantalum carbide coating film may contain a trace amount of an atom other than carbon and tantalum to the extent that such an atom does not interfere with the effects of the present invention. For example, the tantalum carbide coating film may contain an impurity element and/or a doping element other than carbon and tantalum at a concentration of 10,000 mass ppm or less.

### Film Thickness

When the film thickness of the tantalum carbide coating film is too small, gases emitted from the carbon substrate may pass through the tantalum carbide coating film and have adverse effects on semiconductor single crystals. On the other hand, when the film thickness of the tantalum carbide coating film is too large, a prolonged deposition time increases the deposition cost. In consideration of all of these aspects, the film thickness of the metal carbide coating film is preferably 10 μm or more and 100 μm or less, and more preferably 20 μm or more and 50 μm or less. The film thickness of the tantalum carbide coating film is a value as measured on the basis of cross-sectional observation of the tantalum carbide coating film under a scanning electron microscope (SEM). Specifically, a cross-sectional image of the tantalum carbide coating film is captured under a scanning electron microscope (SEM), the film thickness of the cross section of the tantalum carbide coating film is measured at five randomly selected points in the image, and the average value of the five measurements is used as the film thickness of the tantalum carbide coating film.

### Arithmetic Surface Roughness Ra

The arithmetic average roughness Ra of the surface of the tantalum carbide coating film is preferably 0.1 μm or more and 9.5 μm or less, and more preferably 2.0 μm or more and 5.5 μm or less. As with the case of the carbon substrate, a larger arithmetic average roughness Ra of the surface of the tantalum carbide coating film may result in cracking and delamination, and when such a tantalum carbide-coated carbon material is used as the components used for semiconductor single-crystal growth and epitaxial growth, the product life may be shortened. The arithmetic average roughness Ra of the surface of the as-deposited tantalum carbide coating film varies according to the arithmetic average roughness Ra of the surface of the carbon substrate and tends to be a slightly smaller than the arithmetic average roughness Ra of the surface of the carbon substrate. The arithmetic average roughness Ra of the surface of the tantalum carbide coating film can be controlled by polishing or the like as well, but this case needs more production steps. Preferably, an appropriate arithmetic average roughness Ra of the surface of the carbon substrate is selected according to the desired arithmetic average roughness Ra of the surface of the tantalum carbide coating film. Here, the arithmetic average roughness Ra is a value as measured according to JIS B 0633:2001 (ISO 4288:1996).

### Method for Producing the Tantalum Carbide-Coated Carbon Material

The tantalum carbide-coated carbon material according to one embodiment of the present invention can be produced by forming a tantalum carbide layer on the surface of a carbon substrate. For example, the tantalum carbide coating film can be formed on the surface of the carbon substrate by chemical vapor deposition (CVD), sintering, carbonization, or the like. Among these techniques, CVD is a preferable technique for forming the tantalum carbide coating film because CVD enables the formation of a uniform and dense tantalum carbide coating film.

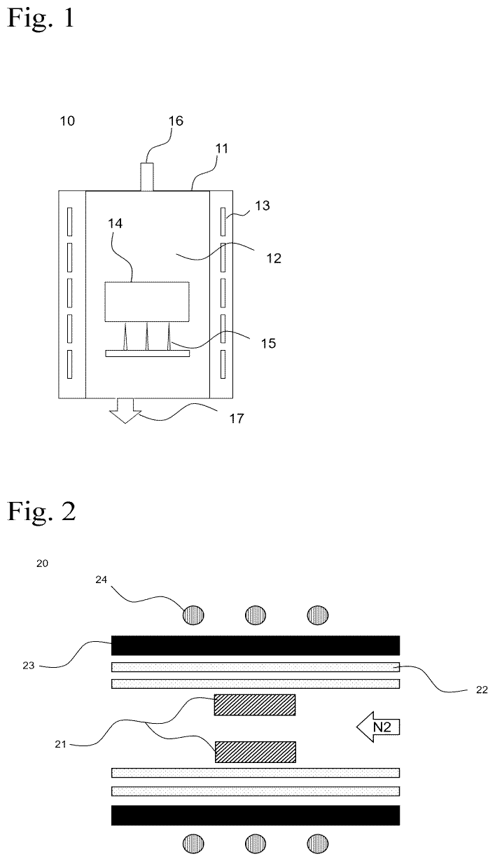

Furthermore, CVD includes thermal CVD, photo CVD, and plasma-enhanced CVD. The tantalum carbide layer can be formed by, for example, thermal CVD. Thermal CVD has some advantages such as using an apparatus with a relatively simple configuration and not causing plasma-induced damage in carbon substrates. For the formation of the tantalum carbide coating film by thermal CVD, for example, a hot-wall low-pressure CVD apparatus 10 as shown in FIG. 1 can be used. In the hot-wall low-pressure CVD apparatus 10, a carbon substrate 14 is supported by a support means 15 in a reaction chamber 12 provided with a heater 13, a source supply unit 16, an exhaust unit 17, and others.

The method for producing the tantalum carbide-coated carbon material according to one embodiment of the present invention will be described with reference to FIG. 1.

First, a carbon substrate 14 is placed in a reaction chamber 12 of a hot-wall low-pressure CVD apparatus 10. The carbon substrate 14 is supported by a support means 15 having three support parts each having a sharply pointed tip.

Next, the reaction chamber 12 is heated. For example, the reaction chamber 12 is heated under the conditions of an atmospheric pressure of 10 to 1,000 Pa and a temperature of 800 to 2,200° C.

Then, a tantalum carbide coating film is formed on the surface of the carbon substrate 14. As source gases, a carbon atom-containing compound gas such as methane (CH₄), hydrogen (H₂) gas, and a tantalum halide gas such as tantalum pentachloride (TaCl₅) are supplied into the reaction chamber 12 from a source supply unit 16. The tantalum halide gas can be generated, for example, by heating and vaporizing a tantalum halide, by reacting a tantalum metal with a halogen gas, or by other methods. Then, the source gases supplied from the source supply unit 16 are subjected to a thermal CVD reaction at a high temperature of 800 to 2,200° C. under a low pressure of 1 to 1,000 Pa to form a tantalum carbide coating film on the carbon substrate 14.

The above-described tantalum carbide-coated carbon material according to one embodiment of the present invention is one example of the metal carbide-coated carbon material according to the present invention, and the metal carbide-coated carbon material according to the present invention is not limited to the tantalum carbide-coated carbon material according to one embodiment of the present invention. In the metal carbide-coated carbon material according to the present invention, the metal carbide constituting the metal carbide coating film covering the carbon substrate is not limited to tantalum carbide. For example, niobium carbide, zirconium carbide, hafnium carbide, tungsten carbide, and other carbides can be used as the metal carbide constituting the metal carbide coating film covering the carbon substrate. In addition, a combination of two or more metal carbides selected from the group consisting of tantalum carbide, niobium carbide, zirconium carbide, hafnium carbide, and tungsten carbide may be used as the metal carbide constituting the metal carbide coating film covering the carbon substrate. Among tantalum carbide, niobium carbide, zirconium carbide, hafnium carbide, and tungsten carbide, tantalum carbide is preferable because it has the highest melting point and also has superior chemical stability, strength, and corrosion resistance.

### EXAMPLES

Hereinafter, examples are provided to describe the present invention in more detail, but the present invention is not limited thereto.

Metal carbide-coated carbon materials of Examples 1 to 14 and Comparative Examples 1 to 4 were produced as follows.

### Example 1

First, isotropic graphite doped with aluminum, iron, magnesium, titanium, silicon, calcium, vanadium, nickel, sodium, potassium, and sulfur was prepared. The isotropic graphite was processed into hollow cylindrical shapes with an outer diameter of 40 mm, an inner diameter of 30 mm, and a height of 30 mm, and each of these was used as carbon substrate 14. The arithmetic average roughness Ra of the surface of this carbon substrate was 6.0 μm, and the linear thermal expansion coefficient of the carbon substrate 14 was 7.0×10⁻⁶/° C. Regarding the linear thermal expansion coefficient of the carbon substrate, a thermomechanical analyzer (TMA7300) manufactured by Hitachi High-Tech Corporation was used, and the value of the thermal expansion coefficient in the temperature ranging from 200° C. to 1,200° C. was used.

Next, as shown in FIG. 1, the carbon substrate 14 was placed in a reaction chamber 12 of a hot-wall low-pressure CVD apparatus 10. The carbon substrate 14 was supported by a support means 15 having three support parts each having a sharply pointed tip. For this support, the tip of each support part was in contact with the outer surface of the carbon substrate 14 in a truncated conical tubular shape, the outer surface of the carbon substrate 14 in a bottomed hollow cylindrical shape, the bottom surface of a disk shape, and the outer surface of a hollow cylindrical shape.

Then, from the source supply unit 16, methane (CH₄) gas was supplied at a flow rate of 0.25 SLM, argon (Ar) gas as a carrier gas was supplied at a flow rate of 1.0 SLM, hydrogen (H₂) gas was supplied at a flow rate of 0.125 SLM, and tantalum pentachloride (TaCl₅), which was heated and vaporized at a temperature of 220° C., was supplied at a flow rate of 0.25 SLM. These gases were reacted in the reaction chamber 12 under the conditions of an atmospheric pressure of 100 Pa and a temperature of 1,250° C. to form a tantalum carbide coating film on the entire surface of the carbon substrate 14.

The carbon substrate 14 covered with the tantalum carbide coating film was taken out from the reaction chamber 12. Thus, hollow cylinders each made of the tantalum carbide-coated carbon material were fully fabricated.

### Examples 2 to 5

Isotropic graphite doped with aluminum, iron, magnesium, titanium, silicon, calcium, vanadium, nickel, sodium, potassium, and sulfur was prepared such that the doping amounts were different from those in Example 1. Except for this, hollow cylinders were fabricated and evaluated in the same manner as in Example 1.

### Example 6

Hollow cylinders were fabricated and evaluated in the same manner as in Example 1, except that the flow rate of hydrogen (H₂) gas was changed to 0.15 SLM, the flow rate of tantalum pentachloride (TaCl₅) was changed to 0.3 SLM, and the film thickness was changed to 10 μm by shortening the deposition time.

### Example 7

Hollow cylinders were fabricated and evaluated in the same manner as in Example 1, except that the flow rate of hydrogen (H₂) gas was changed to 0.15 SLM and the film thickness was changed to 50 μm by extending the deposition time.

### Example 8

Hollow cylinders were fabricated and evaluated in the same manner as in Example 1, except that the arithmetic average roughness Ra of the surface of the carbon substrate 14 was changed to 0.1 μm by polishing the surface of the carbon substrate 14.

### Example 9

Hollow cylinders were fabricated and evaluated in the same manner as in Example 1, except that the arithmetic average roughness Ra of the surface of the carbon substrate 14 was changed to 10 μm by sandblasting the surface of the carbon substrate 14 by shooting an abrasive.

### Example 10

Hollow cylinders were fabricated and evaluated in the same manner as in Example 1, except that the metal chloride was changed from tantalum pentachloride (TaCl₅) to niobium pentachloride (NbCl₅) and NbCl₅ was supplied at a flow rate of 0.25 SLM.

### Example 11

Hollow cylinders were fabricated and evaluated in the same manner as in Example 1, except that the metal chloride was changed from tantalum pentachloride (TaCl₅) to hafnium tetrachloride (HfCl₄) and HfCl₄ was supplied at a flow rate of 0.25 SLM.

### Example 12

Hollow cylinders were fabricated and evaluated in the same manner as in Example 1, except that the metal chloride was changed from tantalum pentachloride (TaCl₅) to zirconium tetrachloride (ZrCl₄) and ZrCl₄ was supplied at a flow rate of 0.25 SLM.

### Example 13

Hollow cylinders were fabricated and evaluated in the same manner as in Example 1, except that the metal chloride was changed from tantalum pentachloride (TaCl₅) to tungsten pentachloride (WCl₅) and WCl₅ was supplied at a flow rate of 0.25 SLM.

### Example 14

Hollow cylinders were fabricated and evaluated in the same manner as in Example 1, except that a mixed gas of tantalum pentachloride (TaCl₅) and niobium pentachloride (NbCl₅) (TaCl₅:NbCl₅=100:1) as a metal chloride was supplied at a flow rate of 0.25 SLM.

### Comparative Example 1

Hollow cylinders were fabricated and evaluated in the same manner as in Example 1, except that isotropic graphite doped with aluminum, iron, magnesium, titanium, silicon, calcium, vanadium, nickel, sodium, potassium, and sulfur was prepared such that the doping amounts were different from those in Example 1; the flow rate of hydrogen (H₂) gas was changed to 0 SLM; and the flow rate of tantalum pentachloride (TaCl₅) was changed to 0.5 SLM.

### Comparative Example 2

Hollow cylinders were fabricated and evaluated in the same manner as in Example 1, except that isotropic graphite doped with aluminum, iron, magnesium, titanium, silicon, calcium, vanadium, nickel, sodium, potassium, and sulfur was prepared such that the doping amounts were different from those in Example 1; and the film thickness of the tantalum carbide coating film was changed to 2 μm by shortening the deposition time.

### Comparative Example 3

Hollow cylinders were fabricated and evaluated in the same manner as in Example 1, except that isotropic graphite doped with aluminum, iron, magnesium, titanium, silicon, calcium, vanadium, nickel, sodium, potassium, and sulfur was prepared such that the doping amounts were different from those in Example 1; and the arithmetic average roughness Ra of the surface of the carbon substrate 14 was changed to 32 μm. The results are shown in Table 1.

### Comparative Example 4

Hollow cylinders were fabricated and evaluated in the same manner as in Example 1, except that isotropic graphite doped with aluminum, iron, magnesium, titanium, silicon, calcium, vanadium, nickel, sodium, potassium, and sulfur was prepared such that the doping amounts were different from those in Example 1; and the arithmetic average roughness Ra of the surface of the carbon substrate 14 was changed to 0.05 μm. The results are shown in Table 1.

Hollow cylinders of Examples 1 to 14 and hollow cylinders of Comparative Examples 1 to 4 were subjected to the following evaluations.

### Film Thickness of the Metal Carbide Coating Film

The film thickness of the metal carbide coating film was measured on the basis of cross-sectional observation of the metal carbide coating film under a scanning electron microscope (SEM).

### Surface Arithmetic Average Roughness Ra

The arithmetic average roughness Ra of the surface of the carbon substrate and the arithmetic average roughness Ra of the surface of the metal carbide coating film on the surface of the carbon substrate were measured using a Surftest SJ-210 manufactured by Mitutoyo Corporation.

### Elemental Concentrations in the Carbon Substrate

### Measurement of Sulfur Concentration

The concentration of sulfur in the carbon substrate was measured using a trace sulfur analyzer (manufactured by Nittoseiko Analytech Co., Ltd., trade name “TS-100”).

### (1) Sample Adjustment Method

The metal carbide-coated carbon material after the deposition was cut out, and the metal carbide coating film was delaminated to leave the carbon substrate alone. The carbon substrate was wrapped in a piece of Teflon (registered trademark) sheet, crushed with a hammer, and the coarse powder was ground in a B₄C mortar into fine powder, which was used as a measurement sample.

### (2) Measurement of Sulfur Concentration

A 10-mg measurement sample was combusted at 1,000° C. in an oxygen atmosphere, the generated SOx was analyzed, and the concentration of sulfur in the carbon substrate was calculated.

Concentrations of Elements Other than Sulfur

The tantalum carbide coating film was delaminated from the metal carbide-coated carbon material, and the metal concentrations in the underlying carbon substrate were measured using an ICP-MS analytical instrument (inductively coupled plasma mass spectrometer) (900° C. pyrolysis/gas analysis) (manufactured by Agilent Technologies, Inc., trade name “Agilent 7900”). Thus, the concentrations of the elements other than sulfur were determined.

### (1) Sample Adjustment Method

The metal carbide-coated carbon material was cut out, and the metal carbide coating film was delaminated to leave the carbon substrate alone. The carbon substrate was wrapped in a piece of Teflon (registered trademark) sheet, crushed with a hammer, and the coarse powder was ground in a B₄C mortar into fine powder. Slightly more than 0.1 g of this fine powder was weighed in a microwave digestion vessel and digested according to the digestion recipe described below. Between the STEPs, air-cooling was performed until the temperature decreased to 40° C.

### Digestion Recipe

STEP 1: HNO₃: 5 mL+H₂SO₄: 2.5 mL (80° C.×2 min, 60° C.×3 min, 220° C.×20 min, 230° C.×30 min)
STEP 2: Add HClO₄: 0.5 mL (240° C.×25 min, 240° C.×25 min)

The resulting solution was transferred to a 30-mL crucible and heated at 380° C. to dryness. After drying, the metal residue was dissolved in a small amount of nitric acid and cooled. To this, a trace amount of hydrofluoric acid and pure water were added to make a volume of 10 mL. Thus, a measurement solution was prepared.

### (2) Concentration Measurement

The measurement solution was analyzed using the ICP-MS analytical instrument under the conditions described below to determine the concentrations of the elements in the carbon substrate.

### Measurement Conditions

Alkali and alkaline earth metals: Cool Plasma (RF power: 600 W)
Elements other than the above: Hot Plasma (RF power: 1,500 W)

### Method for Measuring the Amount of Corrosion Loss in the Carbon Substrate

FIG. 2 shows a cross-sectional view of a corrosion resistance tester. A metal carbide-coated carbon material 21 in a hollow cylindrical shape with an outer diameter of 40 mm, an inner diameter of 30 mm, and a height of 30 mm was prepared. This was covered with an insulator 22 and placed in a quartz tube 23. The temperature was raised to 2,300° C. by high-frequency induction heating, kept at 2,300° C. for 2 hours after reaching that temperature, and then lowered over 2 hours. The temperature of the heating element was measured with a radiation thermometer.

At the same time as the onset of heating, nitrogen was introduced at a flow rate of 1.0 SLM, and the nitrogen flow was continued until the onset of lowering the temperature. The weight of the metal carbide-coated carbon material before and after heating was measured, and (weight after heating−weight before heating)×100 was used as the amount of weight change (mg) of the metal carbide-coated carbon material.

The measurement temperature range in thermal desorption spectroscopy (TDS) is up to 1,500° C., and TDS is not applicable to the analysis of outgassing in a high-temperature environment of 1,600 to 2,300° C. as in the crystal growth and epitaxial growth steps for wide-bandgap semiconductors. Therefore, outgassing in a high-temperature environment is indirectly measured by measuring the amount of weight change of the carbon substrate. That is, a greater amount of weight change of the carbon substrate indicates a larger amount of outgassing in a high-temperature environment.

The results of previous studies have shown that when carbon substrates are heated to around 2,200° C., they react with nitrogen to generate gases such as cyanides and cyanogens, and as a result, become corroded. Reference 2 (G. J. Tennenhouse, J. A. Mangels, Journal of Materials Science Letters, 1, 1982, 282-284) also reports that the reaction of N₂ and carbon generates cyanogens.

In addition, according to the above-mentioned NPL 1, the results of TDS show that saturation has been reached at 1,500° C., and it seems that outgassing of hydrocarbons and the like previously adsorbed on the carbon substrate itself does not have that much influence in a high-temperature environment of 1,600 to 2,300° C. Therefore, the weight change at 2,300° C. is considered to be attributed to the reaction of N₂ and carbon. Further, the metals contained in the substrate may have been involved as catalysts for this reaction, seemingly causing the difference in the amount of weight change.

### Method for Measuring the Adhesion Strength of the Metal Carbide Coating Film

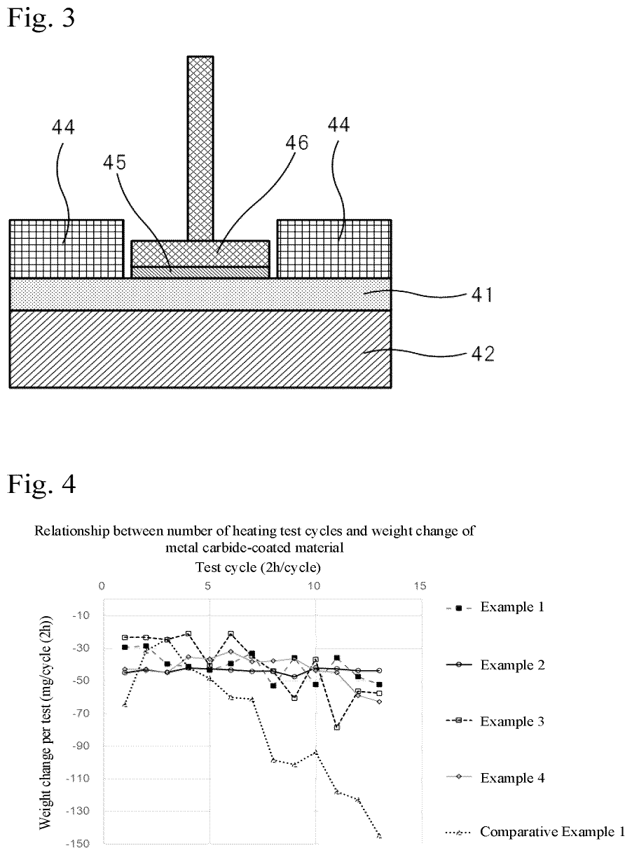

The measurement of the adhesion strength of the metal carbide coating film was performed using a thin film adhesion strength tester (manufactured by Quad Group Inc., trade name “Romulus”). As shown in FIG. 3, a metal carbide coating film 41 and a stud pin 46 were bonded together with an adhesive 45, the metal carbide coating film was firmly held with a holding jig 44, and the stud pin 46 was pulled. The stress at which the metal carbide coating film 41 was delaminated was measured. Five measurements were taken, and the average value calculated from the five measurements was used as the adhesion strength of the metal carbide coating film.

The production conditions for Examples 1 to 14 and Comparative Examples 1 to 4 are shown in Table 1.

TABLE 1

| | | Flow rate of | Flow rate of | Flow rate of | Flow rate of |
|---|---|---|---|---|---|
| | Metal halide | metal halide | CH₃ gas | H₂ gas | Ar gas |
| | gas species | gas (SLM) | (SLM) | (SLM) | (SLM) |
| Example 1 | TaCl₅ | 0.25 | 0.25 | 0.125 | 1.00 |
| Example 2 | TaCl₅ | 0.25 | 0.25 | 0.125 | 1.00 |
| Example 3 | TaCl₅ | 0.25 | 0.25 | 0.125 | 1.00 |
| Example 4 | TaCl₅ | 0.25 | 0.25 | 0.125 | 1.00 |
| Example 5 | TaCl₅ | 0.25 | 0.25 | 0.125 | 1.00 |
| Example 6 | TaCl₅ | 0.3 | 0.25 | 0.15 | 1.00 |
| Example 7 | TaCl₅ | 0.25 | 0.25 | 0.15 | 1.00 |
| Example 8 | TaCl₅ | 0.25 | 0.25 | 0.125 | 1.00 |
| Example 9 | TaCl₅ | 0.25 | 0.25 | 0.125 | 1.00 |
| Example 10 | NbCl₆ | 0.25 | 0.25 | 0.125 | 1.00 |
| Example 11 | HfCl₄ | 0.25 | 0.25 | 0.125 | 1.00 |
| Example 12 | ZrCl₄ | 0.25 | 0.25 | 0.125 | 1.00 |
| Example 13 | WCl₆ | 0.25 | 0.25 | 0.125 | 1.00 |
| Example 14 | TaCl₅ + NbCl₆ | 0.25 | 0.25 | 0.125 | 1.00 |
| Comparative | TaCl₅ | 0.5 | 0.25 | 0 | 1.00 |
| Example 1 | | | | | |
| Comparative | TaCl₅ | 0.25 | 0.25 | 0.125 | 1.00 |
| Example 2 | | | | | |
| Comparative | TaCl₅ | 0.25 | 0.25 | 0.125 | 1.00 |
| Example 3 | | | | | |
| Comparative | TaCl₅ | 0.25 | 0.25 | 0.125 | 1.00 |
| Example 4 | | | | | |

| | Deposition temperature for | Deposition time for |
|---|---|---|
| | metal carbide coating film (° C.) | metal carbide coating film (hr) |
| Example 1 | 1250 | 10 |
| Example 2 | 1250 | 10 |
| Example 3 | 1250 | 10 |
| Example 4 | 1250 | 10 |
| Example 5 | 1250 | 10 |
| Example 6 | 1250 | 3 |
| Example 7 | 1250 | 17 |
| Example 8 | 1250 | 10 |
| Example 9 | 1250 | 10 |
| Example 10 | 1250 | 10 |
| Example 11 | 1250 | 10 |
| Example 12 | 1250 | 10 |
| Example 13 | 1250 | 10 |
| Example 14 | 1250 | 10 |
| Comparative | 1250 | 10 |
| Example 1 | | |
| Comparative | 1250 | 0.5 |
| Example 2 | | |
| Comparative | 1250 | 10 |
| Example 3 | | |
| Comparative | 1250 | 10 |
| Example 4 | | |

The evaluation results of Examples 1 to 4 and Comparative Example 1 are shown in FIG. 4, and the evaluation results of Examples 1 to 14 and Comparative Examples 1 to 4 are shown in Table 2.

TABLE 2

Elemental concentrations in substrate (mass ppm)

| | Al | Fe | Mg | Ti | Si | Ca |
|---|---|---|---|---|---|---|
| Example 1 | 2.7 | 6.1 | 0.4 | 0.9 | 24 | 2.8 |
| Example 2 | 0.4 | 3.8 | 0.2 | 0.9 | 2.1 | 2.1 |
| Example 3 | 4 | 5.9 | 0.5 | 33 | 14 | 31 |
| Example 4 | 6.5 | 16 | 1.1 | 9.8 | 620 | 27 |
| Example 5 | 620 | 3321 | 9 | 1825 | 420 | 1550 |
| Example 6 | 2.7 | 6.1 | 0.4 | 0.9 | 24 | 2.8 |
| Example 7 | 2.7 | 6.1 | 0.4 | 0.9 | 24 | 2.8 |
| Example 8 | 2.7 | 6.1 | 0.4 | 0.9 | 24 | 2.8 |
| Example 9 | 2.7 | 6.1 | 0.4 | 0.9 | 24 | 2.8 |
| Example 10 | 2.7 | 6.1 | 0.4 | 0.9 | 24 | 2.8 |
| Example 11 | 2.7 | 6.1 | 0.4 | 0.9 | 24 | 2.8 |
| Example 12 | 2.7 | 6.1 | 0.4 | 0.9 | 24 | 2.8 |
| Example 13 | 2.7 | 6.1 | 0.4 | 0.9 | 24 | 2.8 |
| Example 14 | 2.7 | 6.1 | 0.4 | 0.9 | 24 | 2.8 |
| Comparative | 580 | 22500 | 31 | 2200 | 1230 | 880 |
| Example 1 | | | | | | |
| Comparative | 981 | 2.5 | 4173 | 21330 | 4971 | 3587 |
| Example 2 | | | | | | |
| Comparative | 4934 | 27.5 | 929 | 1572 | 1134 | 63 |
| Example 3 | | | | | | |
| Comparative | 1675 | 24610 | 2027 | 21540 | 1211 | 3895 |
| Example 4 | | | | | | |

Elemental concentrations in substrate (mass ppm)

| | V | Ni | Na | K | S | Total |
|---|---|---|---|---|---|---|
| Example 1 | 0.2 | 0.2 | 2.9 | 0.1 | 0.1 | 40 |
| Example 2 | 0.1 | 0.2 | 0.1 | 0.1 | 0.1 | 10 |
| Example 3 | 4.2 | 7.7 | 3.2 | 0.4 | 20 | 124 |
| Example 4 | 4.6 | 1.4 | 7.7 | 2 | 10 | 706 |
| Example 5 | 953 | 12 | 17 | 11 | 30 | 8768 |
| Example 6 | 0.2 | 0.2 | 2.9 | 0.1 | 0.1 | 40 |
| Example 7 | 0.2 | 0.2 | 2.9 | 0.1 | 0.1 | 40 |
| Example 8 | 0.2 | 0.2 | 2.9 | 0.1 | 0.1 | 40 |
| Example 9 | 0.2 | 0.2 | 2.9 | 0.1 | 0.1 | 40 |
| Example 10 | 0.2 | 0.2 | 2.9 | 0.1 | 0.1 | 40 |
| Example 11 | 0.2 | 0.2 | 2.9 | 0.1 | 0.1 | 40 |
| Example 12 | 0.2 | 0.2 | 2.9 | 0.1 | 0.1 | 40 |
| Example 13 | 0.2 | 0.2 | 2.9 | 0.1 | 0.1 | 40 |
| Example 14 | 0.2 | 0.2 | 2.9 | 0.1 | 0.1 | 40 |
| Comparative | 1323 | 656 | 23 | 13 | 521 | 29944 |
| Example 1 | | | | | | |
| Comparative | 3907 | 2669 | 3814 | 121 | 2272 | 47707 |
| Example 2 | | | | | | |
| Comparative | 24610 | 1670 | 3126 | 220 | 2913 | 40979 |
| Example 3 | | | | | | |
| Comparative | 20230 | 3108 | 4984 | 212 | 3694 | 86974 |
| Example 4 | | | | | | |

| | | Surface roughness Ra | | | Weight change in |
|---|---|---|---|---|---|
| | | (μm) | | | corrosion resistance |
| | Film | Carbon | Metal carbide | Adhesion strength | test |
| | thickness | substrate | coating film | (MPa) | (mg) |
| Example 1 | 30 | 6 | 5.5 | 18.5 | −555 |
| Example 2 | 30 | 6 | 5.5 | 19.6 | −525 |
| Example 3 | 30 | 6 | 5.5 | 24.6 | −571 |
| Example 4 | 30 | 6 | 5.5 | 20.1 | −534 |
| Example 5 | 30 | 6 | 5.5 | 25.3 | −595 |
| Example 6 | 10 | 6 | 5.5 | 15.6 | −559 |
| Example 7 | 50 | 6 | 5.5 | 27.4 | −557 |
| Example 8 | 30 | 0.1 | 1.5 | 11.3 | −559 |
| Example 9 | 30 | 10 | 9.5 | 40.5 | −558 |
| Example 10 | 30 | 6 | 5.5 | 21.3 | −560 |
| Example 11 | 30 | 6 | 5.5 | 22.6 | −563 |
| Example 12 | 30 | 6 | 5.5 | 27.5 | −567 |
| Example 13 | 30 | 6 | 5.5 | 25.5 | −564 |
| Example 14 | 30 | 6 | 5.5 | 25.5 | −559 |
| Comparative | 30 | 6 | 5.5 | 15.4 | −1013 |
| Example 1 | | | | | |
| Comparative | 2 | 6 | 5.5 | 22.5 | −1025 |
| Example 2 | | | | | |
| Comparative | 30 | 32 | 31.5 | 18.5 | −1060 |
| Example 3 | | | | | |
| Comparative | 30 | 0.05 | 0.01 | 2.1 | −1124 |
| Example 4 | | | | | |

Comparison between the results of Examples 1 to 14 and the results of Comparative Examples 1 to 4 shows that when the total concentration of aluminum, iron, magnesium, titanium, silicon, calcium, vanadium, nickel, sodium, potassium, and sulfur in the carbon substrate was 10 mass ppm or more and 10,000 mass ppm or less, the weight change of the metal carbide-coated carbon material was reduced.

The results of Examples 1 to 4 and the results of Comparative Example 1 as a plot of the weight change per corrosion resistance test (2h) and the number of cycles of use are shown in FIG. 4. In these comparisons, when the total concentration of aluminum, iron, magnesium, titanium, silicon, calcium, vanadium, nickel, sodium, potassium, and sulfur in the carbon substrate was 10 mass ppm or more and 10,000 mass ppm or less, the amount of weight loss per test remained almost unchanged with increasing numbers of tests. On the other hand, in the case of the composition as in Comparative Example 1, the amount of weight loss was shown to increase with increasing numbers of tests.

Comparison between the results of Examples 1, 6, and 7 and the results of Comparative Example 2 shows that when the total concentration of aluminum, iron, magnesium, titanium, silicon, calcium, vanadium, nickel, sodium, potassium, and sulfur in the carbon substrate was 10 mass ppm or more and 10,000 mass ppm or less and the film thickness of the tantalum carbide coating film was 10 μm or more and 100 μm or less, the weight change of the metal carbide-coated carbon material was further reduced. When the film thickness of the tantalum carbide coating film was less than 10 μm, the amount of weight loss was increased. The film thickness of the tantalum carbide coating film exceeding 100 μm is undesirable because of a prolonged deposition time, which increases the deposition cost. Therefore, the film thickness of the tantalum carbide coating film in the range of 10 μm or more and 100 μm or less is preferable.

Comparison between the results of Examples 1, 8, and 9 and the results of Comparative Examples 3 and 4 shows that when the total concentration of aluminum, iron, magnesium, titanium, silicon, calcium, vanadium, nickel, sodium, potassium, and sulfur in the carbon substrate was 10 mass ppm or more and 10,000 mass ppm or less; and the arithmetic average roughness Ra of the surface of the metal carbide coating film was 0.1 μm or more and 9.5 μm or less, or the arithmetic average roughness Ra of the surface of the carbon substrate was 0.1 μm or more and 10.0 μm or less, the weight change of the metal carbide-coated carbon material was further reduced. When the arithmetic average roughness Ra of the surface of the carbon substrate was more than 10 μm, the amount of weight loss was increased. Even when the arithmetic average roughness Ra of the surface of the carbon substrate was less than 0.1 μm, the amount of weight loss was increased.

Comparison among the results of Example 1 and Examples 10 to 14 shows that when the metal carbide coating film was a tantalum carbide coating film, the weight change of the metal carbide-coated carbon material was further reduced.

### REFERENCE SIGNS LIST

10 Hot-wall low-pressure CVD apparatus
11 Top chamber
12 Reaction chamber
13 Heater
14 Carbon substrate
15 Support means
16 Source supply unit
17 Exhaust unit
20 Schematic view of setup for corrosion resistance tester
21 Metal carbide-coated carbon material
22 Insulator
23 Quartz tube
24 Coil
41 Metal carbide coating film
42 Carbon substrate
44 Holding jig
45 Adhesive
46 Stud pin

1. A metal carbide-coated carbon material comprising a carbon substrate containing carbon as a main component and a metal carbide coating film covering at least part of the carbon substrate,
wherein the metal carbide constituting the metal carbide coating film is at least one metal carbide selected from the group consisting of tantalum carbide, niobium carbide, zirconium carbide, hafnium carbide, and tungsten carbide,
wherein the carbon substrate contains at least one element selected from the group consisting of aluminum, iron, magnesium, titanium, silicon, calcium, vanadium, nickel, sodium, potassium, and sulfur, and
wherein the total concentration of aluminum, iron, magnesium, titanium, silicon, calcium, vanadium, nickel, sodium, potassium, and sulfur in the carbon substrate is 10 mass ppm or more and 10,000 mass ppm or less.

2. The metal carbide-coated carbon material according to claim 1, wherein the concentration of iron in the carbon substrate is 1 mass ppm or more and 10,000 mass ppm or less.

3. The metal carbide-coated carbon material according to claim 1, wherein the concentration of titanium in the carbon substrate is 0.1 mass ppm or more and 10,000 mass ppm or less.

4. The metal carbide-coated carbon material according to claim 1, wherein the concentration of magnesium in the carbon substrate is 0.1 mass ppm or more and 10,000 mass ppm or less.

5. The metal carbide-coated carbon material according to claim 1, wherein the concentration of silicon in the carbon substrate is 0.1 mass ppm or more and 10,000 mass ppm or less.

6. The metal carbide-coated carbon material according to claim 1, wherein the concentration of calcium in the carbon substrate is 0.1 mass ppm or more and 10,000 mass ppm or less.

7. The metal carbide-coated carbon material according to claim 1, wherein the concentration of vanadium in the carbon substrate is 0.1 mass ppm or more and 10,000 mass ppm or less.

8. The metal carbide-coated carbon material according to claim 1, wherein the concentration of sodium in the carbon substrate is 0.1 mass ppm or more and 10,000 mass ppm or less.

9. The metal carbide-coated carbon material according to claim 1, wherein the concentration of potassium in the carbon substrate is 0.1 mass ppm or more and 10,000 mass ppm or less.

10. The metal carbide-coated carbon material according to claim 1, wherein the concentration of sulfur in the carbon substrate is 0.1 mass ppm or more and 10,000 mass ppm or less.

11. The metal carbide-coated carbon material according to claim 1, wherein the metal carbide coating film has a film thickness of 10 μm or more and 100 μm or less.

12. The metal carbide-coated carbon material according to claim 1, wherein the surface of the metal carbide coating film has an arithmetic average roughness Ra of 0.1 μm or more and 9.5 μm or less.

13. The metal carbide-coated carbon material according to claim 1, wherein the surface of the carbon substrate has an arithmetic average roughness Ra of 0.1 μm or more and 10.0 μm or less.

14. The metal carbide-coated carbon material according to claim 1, wherein the metal carbide constituting the metal carbide coating film is tantalum carbide.
